(19) United States
(12) Patent Application Publication
(10) Pub. No.: US 2018/0174762 A1
(43) Pub. Date: Jun. 21, 2018

(54) HYBRID ORGANIC-INORGANIC ELECTRON SELECTIVE OVERLAYERS FOR HALIDE PEROVOSKITES

(71) Applicant: UChicago Argonne, LLC, Chicago, IL (US)

(72) Inventors: In Soo Kim, Woodridge, IL (US); Alex B. Martinson, Naperville, IL (US)

(21) Appl. No.: 15/381,741

(22) Filed: Dec. 16, 2016

(51) Int. Cl. H01G 9/20; H01L 51/42; H01L 51/44

(52) U.S. Cl. CPC H01G 9/2013; H01G 9/2077; H01L 51/448; H01L 51/424; H01L 51/422

(57) ABSTRACT

A significant improvement in the stability of inverted perovskite solar cells against liquid water and high operating temperature (100° C.) by integrating an ultrathin overlayer in the electron transport layer via atomic layer deposition (ALD). These unencapsulated inverted devices exhibit stable operation over at least 10 hours when subjected to high thermal stress (100° C.) in ambient environments, as well as upon direct contact with a droplet of water without further encapsulation.

The United States Government claims certain rights in this invention pursuant to Contract No. W-31-109-ENG-38 between the United States Government and the University of Chicago and/or pursuant to DE-AC02-06CH11357 between the United States Government and UChicago Argonne, LLC representing Argonne National Laboratory.

### TECHNICAL FIELD

The present disclosure relates generally to apparatus, compositions, and methods relating to thin films, specifically to hybrid organic-inorganic extraction layers in a photovoltaic architecture.

### BACKGROUND

Perovskites are known for use in various solar applications. In particular, hybrid perovskites exhibit nearly ideal photo-physical characteristics for applications in solar energy conversion including a direct and tunable bandgap of 1.2-2.0 eV, weak exciton binding energy, long carrier diffusion lengths. Moreover, the feasibility of large-area processing with short energy payback time clearly distinguishes hybrid perovskites as an impactful alternative to other PV technologies. Hybrid perovskite based solar cells have previously been shown to surpass conversion efficiencies of ˜22%.

However, despite the benefits of known hybrid perovskite constructs, they still exhibit certain limitations and no devices have been reported to pass the damp heat test—85° C. and 85% relative humidity (RH) for 1000 hours—owing largely to the modest stability of hybrid perovskite photoabsorbers against high temperature and moisture.

In addition, present photoabsorbers suffer due to the fragility of the structure. This fragility limits the possible device architectures, materials, and processing methods that may be applied to new device designs. Among various attempts to improve operational stability, the most successful of which demonstrate resistance to continuous stress of at least 50° C. or 50% RH operation, include carbon contact based encapsulation, single walled carbon nanotube (CNT) embedded in polymer matrix, solution-processed layers, sputtered ITO on a nanoparticle buffer overlayer, and layered two-dimensional perovskites.

However, there remains a need for an improved approach to thin layer perovskite structures.

### SUMMARY

Embodiments described herein relate generally to an apparatus comprising a substrate, an electrode material disposed on the substrate, a hole extraction layer disposed between the electrode and a perovskite layer. The apparatus further includes a buffer layer deposited on the perovskite layer; and an overcoat layer deposited on the buffer layer.

Another embodiment relates to a method of making a device comprising: providing a substrate with a transparent electrode material thereon; depositing a hole extraction layer on the transparent electrode material; depositing a perovskite layer on the compact hole extraction layer; depositing an buffer layer on a perovskite layer; and depositing, by atomic layer deposition, a metal halide overlayer on the organic buffer layer.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1A shows a representative device architecture in an exploded view, FIG. 1B illustrates a false color SEM image of an one embodiment of an inverted perovskite photovoltaic device (scale bar 500 nm), and FIG. 1C illustrates one embodiment of an idealized energy level diagram of the corresponding device architecture.

FIG. 2 shows current density-voltage (J-V) characteristics of a passivated inverted perovskite PV device where Circle solid lines represent dark and illumination under simulated AM 1.5 G irradiation with 100 mW/cm and triangle lines represent the control device.

FIG. 3A shows time dependent X-ray diffraction spectra of standard planar perovskite device (Left) and inverted perovskite device (right) before and after thermal soaking at 100° C.; FIG. 3B shows a wide range X-ray diffraction spectrum of the inverted device after thermal soaking at 100° C. for 24 hours, which corresponds to the red curve of the inverted device (right panel) in FIG. 3A.

FIG. 4 shows a graph of stability of control and inverted perovskite devices without additional encapsulation upon thermal soaking at 100° C. extracted from I-V measurements.

FIGS. 5A-5B show wet device operation of inverted perovskite device (a) before and (b) after the I-V measurements.

FIG. 6 shows FTIR spectra of unpassivated (glass/perovskite/PCBM) and passivated (glass/perovskite/PCBM/a-TiO2) samples after thermal cycling at 100° C. in air. Characteristic vibrational modes of methylammonium (CH3NH2+) ions disappear in the unpassivated sample (black curve) upon degradation, whereas CH3NH2+ species are preserved in the passivated sample. Measurements were performed with samples prepared on glass without contact electrodes to minimize complexity of FTIR measurements.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION OF VARIOUS EMBODIMENTS

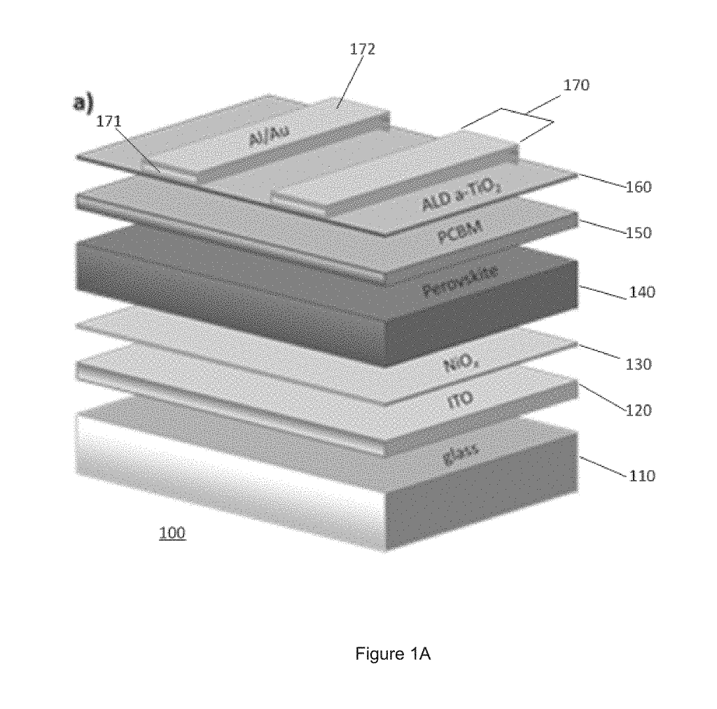

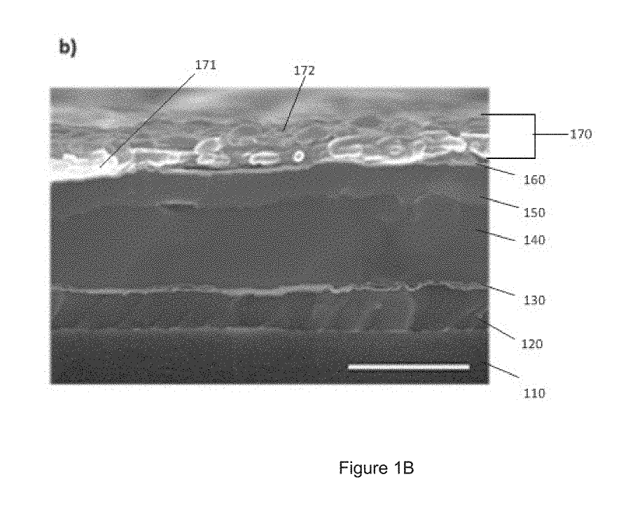

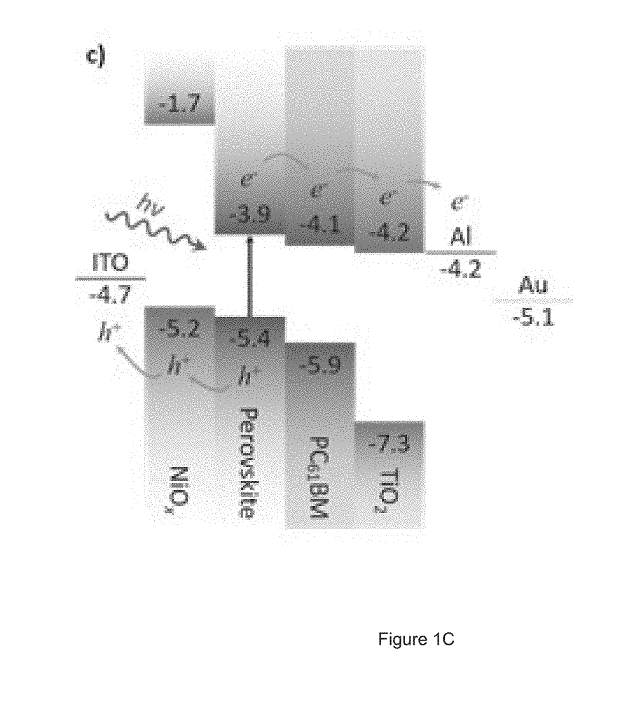

Embodiments described herein relate generally to a simple route to liquid water and temperature resistant hybrid perovskite devices utilizing an inverted hybrid perovskite architecture with several improvements. For example, some embodiments relate to structure having a hybrid organic-inorganic electron extraction layer, for example comprising organic [6,6]-phenyl-C₆₁-butyric acid methyl ester (PCBM) buffer or interfacial layer and inorganic amorphous atomic layer deposited (ALD TiO₂ layer. FIG. 1A illustrates one embodiment of a perovskite device 100 having a substrate 110, an electrode material 120, a hole extraction layer 130, a perovskite layer 140, a buffer layer 150, an overlayer 160, and one or more electrodes 170, such as comprising an electrode base layer 171 and an electrode secondary layer 172.

An inverted hybrid perovskite apparatus is provided, such as one having a substrate 110, for example glass, with a transparent electrode material 120, such as ITO, FTO, or any other acceptable transparent conductive layer. In an alternative embodiment, metal grids or nanowires can be used as transparent contacts, as well as graphene and carbon nanotubes. This transparent electrode material 120 is preferably sufficiently thick to provide <50 ohms sheet resistance, for example about 100 nm of ITO or 300 nm of FTO.

In some embodiments, first, a hole extraction layer 130 comprises a compact selective hole transport material, such known hygroscopic materials for example polymers like PEDOT:PSS or, in one embodiment, NiOₓ or, in another embodiment, CuSCN. A list of perovskite compatible hole transport materials may be found at L. Calió, S. Kazim, M. Grätzel, S. Ahmad, Angew. Chem Int. Ed. 2016, 55, 14522 (table 1), incorporated herein by reference. In one embodiment, the hole extraction layer 130 may be a hygroscopic underlayer without an overlayer. Alternatively, a metal oxide compact hole extraction overlay (not shown in FIG. 1A) may be present (between the perovskite and the transparent electrode material). In one embodiment, the hole extraction layer 130, such as NiOₓ is deposited over the transparent electrode 120 to replace a more traditional hygroscopic organic hole extraction material, for example PEDOT:PSS. This layer 130 is, in one embodiment, up to 100 nm thick, for example 3 nm to 30 nm and in one embodiment about 13 nm thick.

A perovskite layer 140 is deposited over the transparent electrode material, or in embodiments with a hole extraction layer 130, over that layer. The perovskite layer serves as a photoabsorber. This perovskite layer 140 is, in one embodiment, about 300 nm to 1000 nm, such as about 500 nm thick. The perovskite of the perovskite layer 130, in one embodiment, has a formula of ABX₃, where A can be methylammonium (MA), formamidinium (FA), or Cs, B can be Pb, Sn, or Bi, and X can be I, Cl, or Br. In one embodiment, the perovskite is FAPbI₃. In another embodiment, the perovskite layer 140 comprises more than one ABX₃ perovskite formulation, such as where the cation (A) in the layer is more than one of MA, FA, and Ce. Similarly, the halide (X) in the layer 140 may be more than one of Br, Cl, I. Thus, a mixture of different perovskites may be utilized in the perovskite layer 140.

In some embodiments, an buffer layer 150 is provided, such as on the perovskite layer 140. The buffer layer 150 in conjunction with an overlayer 160 (described below), form a hybrid electron extraction layer. The buffer layer 150 may comprise an organic buffer layer, for example a fullerene or fullerene derivative. Further, in one embodiment, the organic buffer layer may comprise an organic or inorganic nanoparticle, in a particular embodiment PTEG-1 (fulleropyrrolidine with a triethylene glycol monoethyl ether side chain) orphenyl-C61-butyric acid methyl ester (PC₆₁BM). In one embodiment, the organic buffer layer is one that facilitates the deposition of the overlayer 160, such as a metal oxide layer. In one embodiment, an inorganic buffer layer, such as inorganic nanoparticles, for example ZnO (or doped ZnO), ITO, SnO2, may be used in combination with or in place of the organic buffer layer to form the buffer layer. The buffer layer 150 may be about 5 to 500 nm, in one embodiment about 50 nm thick.

In one embodiment, the overlayer 160 is deposited, such as on the buffer layer. The over layer may, in one embodiment, be a a pinhole-free ultrathin, such as 10 nm or less. The overlayer 160 may comprise a metal oxide layer (such as a n-type metal oxide), metal nitride, or metal sulfide layers, such as ITO, CdS, ZnS. For example, the metal oxide layer may be TiO₂ such as amorphous TiO₂ (a-TiO₂), ZnO or SnO₂. In one embodiment the metal oxide layer is amorphous, however in an alternative embodiment, the metal oxide layer doesn't have to be amorphous though the lack of polycrystalline grain boundaries may improve the passivation/barrier effect. In one embodiment, a plurality of metal oxide layers may be provided as the metal oxide layer. A multilayer stack may be utilized, such as a stack of metal oxides or metal sulfides, e.g. TiO2/metal oxide/TiO2. Further, the metal oxide layer may also be able to improve both passivation and charge transport through a combination of amorphous and crystalline films here. In one embodiment, the deposition of the overlayer 160 is by atomic layer deposition (ALD), such as 50° C. to 200° C. for example at about 100° C. and 1×10-6 Torr to 800 Torr, for example 1 Torr pressure utilizing an ALD pulse cycle timing of 0.001 to 10 seconds. The overlayer 160 is utilized to minimize series resistance while preventing device short circuiting.

One or more electrodes 170 may be deposited on the metal oxide layer. For example, an electrode base layer 171 may utilized and comprise metal. One embodiment comprises aluminum electrodes.

In addition, an electrode secondary layer 172 may be added to the electrodes 170 (such as Al electrodes) and comprise metal. The electrode secondary layer 172 layer comprises, in one embodiment gold to prevent oxidation and delamination of Al upon exposure to liquid water.

One of skill in the art will appreciate that the integration of any metal oxide subsequent to hybrid perovskite deposition without damage is challenging due to the tendency of hybrid perovskites to deteriorate upon exposure to modest temperatures (˜125° C.) and oxidants (H₂O, O₃, H₂O₂). To address these processing barriers, the ability to stabilize hybrid perovskite photoabsorbers via a non-hydrolytic, acetic acid based ALD process that deposits pinhole-free ultrathin oxides directly on the perovskite halide absorber has previously been demonstrated (see, Kim, I. S.; Martinson, A. B. F. Stabilizing Hybrid Perovskites against Moisture and Temperature Via Non-Hydrolytic Atomic Layer Deposited Overlayers. J. Mater. Chem. A 2015, 3, 20092-20096). However, importantly the inconsistent nucleation and sluggish charge extraction observed prevent the use of these layers in efficient photovoltaics.

One embodiment of an idealized device architecture and corresponding false color SEM image is illustrated in FIG. 1B, alongside the corresponding band diagram in FIG. 1C with energy levels from literature. The desired charge carrier cascade is set up by sandwiching the perovskite absorber between nearly all-oxide charge extraction layers, with the exception of the thin carbon-based PC₆₁BM buffer layer. The hole extraction layer, NiOₓ, selectively transports photogenerated holes from the photoabsorber to the indium tin oxide (ITO) transparent conductive electrode while a PC₆₁BM/a-TiO₂ electron extraction layer selectively shuttles electrons to the metal electrode. The pinhole-free a-TiO₂ (which may extend into the PC₆₁BM buffer layer due to the nature of ALD) doubly serves as a robust (inward and outward) diffusion barrier as will be discussed below.

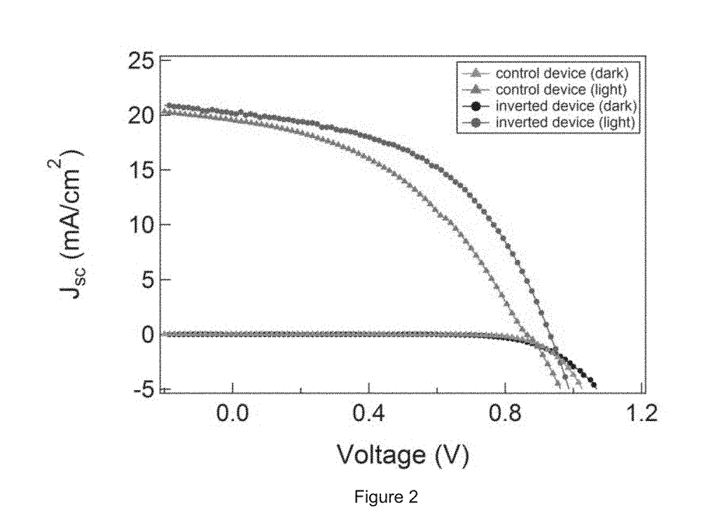

The performance of these unoptimized inverted devices are comparable to an analogous non-inverted planar hybrid perovskite devices utilizing a similar device architecture but with spiro-OMeTAD and ALD derived a-TiO₂ as hole and electron extraction layers. A representative current-voltage (J-V) curve for the inverted perovskite devices is shown in FIG. 2 with detailed device parameters extracted in Table 1. The average short circuit current density (J_{sc}) of 19.7 mA cm⁻² suggests efficient extraction and transport of both photogenerated electrons and holes through hybrid PC₆₁BM/a-TiO₂ and NiOₓ, respectively. The J-V curve of the inverted device with hybrid electron extraction layer exhibits an equal or slightly improved shunt and series resistances extracted from the standard photovoltaic diode equation compared to our best control non-inverted planar hybrid perovskite devices. It is believe that the two-fold increase in the extracted shunt resistance is due to the presence of the PC₆₁BM buffer layer, which limits the photogenerated holes direct access to defect levels in otherwise defective and “leaky” a-TiO₂, significantly reducing the probability of charge recombination at this interface.

An open circuit voltage (V_{oc}) of 0.93 V (slightly higher than even UV-O₃ treated non-inverted a-TiO₂ based hybrid perovskite devices) further supports this hypothesis. The devices exhibit an unexceptional fill factor (FF) of 47.7% as a result of relatively high series resistance to electron transport through the low temperature a-TiO₂ compact layer as well as the NiOₓ layer. Based on the rough morphology of NiOₓ/perovskite layers (FIG. 1A), poor wettability of the perovskite solution on NiOₓ film may also contribute to the subpar fill factor. While the devices exhibit J_{sc} and V_{oc} comparable to many planar devices, the modest fill factor results in a moderate average efficiency (η) of 8.8%.

As discussed above, an inverted ALD oxide design utilizing nanoscale barriers provides a simple and integrated approach to assembling hybrid perovskite solar cells that are more resistant to the environmental stress of high temperature and liquid water. The conformal, amorphous oxide overlayer serves a dual role as both effective diffusion barrier and efficient charge transport layer. The device design is expected to be further transferable to a wide range of even more stable and efficient perovskite halide absorber materials and films morphologies. Device resistance to liquid water further positions these absorbers for the once implausible prospect of direct integration into a photoelectrochemical cell for solar fuel generation. Embodiments of the above described devices where created.

Control Device Fabrication: FTO glass was etched using Zn metal powder and HCl diluted in RO water (1:4 ratio). The substrates were cleaned with warm soapy water followed by ultrasonication in acetone and isopropyl alcohol. A commercial ALD system (Savannah S200, Cambridge Nanotech) was used to deposit compact TiO₂ layers. In-line Entegris Ni filtered nitrogen (N₂) was continuously introduced to the ALD chamber at a flow rate of 10 sccm to achieve a base pressure of ˜0.3 Torr. The sample chamber was kept at 120° C. while tetrakis(dimethylamino) titanium (TDMAT) precursor was kept at 75° C. to achieve reasonable vapor pressure for deposition. Standard pulse times for TDMAT and H₂O were 0.15 and 0.015 s, respectively, with purge times kept constant at 30 s. The TiO₂ films were subsequently treated under UV-O₃ for 10 minutes. Hybrid perovskite solution containing 1:3 ratio of PbCl₂ and MAI in DMF (40 wt %) was stirred for 15 minutes prior to deposition. MAPbI₃₋ₓClₓ films were deposited by spin coating at 3000 rpm for 30 s and baked at 100° C. for 1 hour to remove the solvent. Spiro-OMeTAD was then deposited by spin coating at 3000 rpm for 30 s. The solution was prepared by dissolving 80 mg spiro-OMeTAD in 1 mL chlorobenzene, 28.8 μL of 4 tert-butylpyridine, and 17.5 μL stock solution of 520 mg mL⁻¹ lithium bis(trifluoromethylsulphonyl)imide in acetonitrile. Finally, 100 nm of Au was thermally evaporated on top of the device to form the back contact.

Inverted Device Fabrication: ITO glass was etched using the same procedure as described above for FTO. The substrates were ultrasonically cleaned in acetone and isopropyl alcohol. Pulsed laser deposition was used to deposit 13 nm NiOₓ at room temperature followed by UV-O₃ treatment for 10 minutes. Hybrid perovskite films were deposited using the method described above. Subsequently, PCBM (20 mg dissolved in 1 ml chlorobenzene) was deposited on hybrid perovskites by spin coating at 1000 rpm for 30 s. ALD compact TiO₂ layers were deposited following the procedure described above at 100° C. 100 nm of Al followed by 20 nm of Au was thermally evaporated on top of the device to form the back contact.

Device Characterization: J-V characteristics were measured under simulated AM 1.5 G light (100 mWcm⁻²) using Oriel 300 W Solar Simulator. Light intensity was calibrated using a visible photodiode, which generates photocurrent of 0.7433 mA upon exposure to simulated light. A Keithley 2400 source meter was used for electrical characterization. The active area of all devices was 0.16 cm⁻². The devices were measured in both reverse and forward directions at a scan rate of 5 mV/s with a light soaking time of 15 seconds.

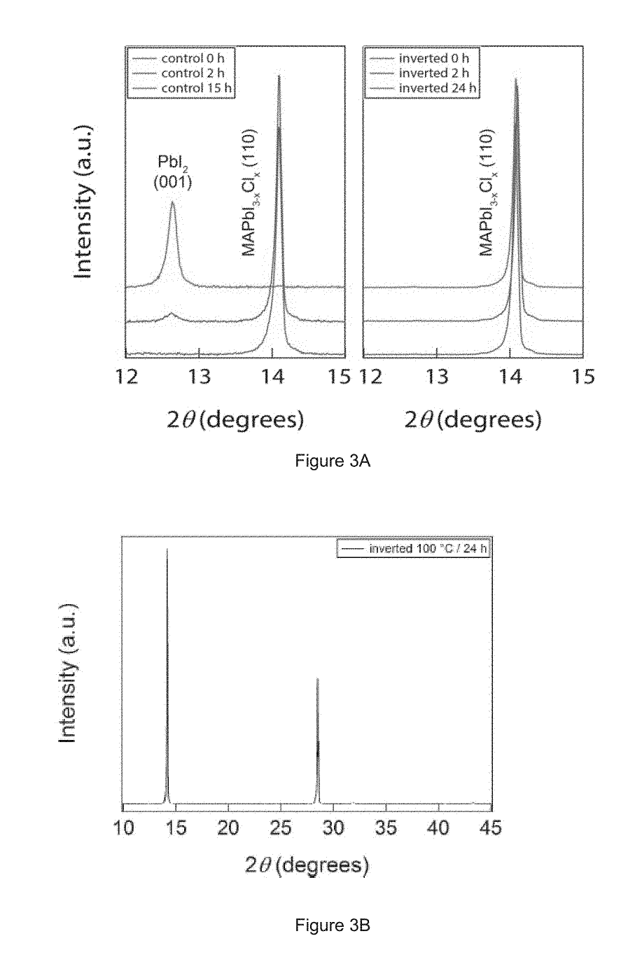

In order to quantify the improvement in thermal stability of these devices, temperature dependent X-ray diffraction (XRD) measurements in air were performed, as shown in FIG. 3A. FIG. 3B shows a wide range X-ray diffraction spectrum of the inverted device after thermal soaking at 100° C. for 24 hours, which corresponds to the red curve of the inverted device (right panel) in FIG. 3A. For control devices, formation of PbI₂ is observed within 2 hours at 100° C., consistent with previous reports. For inverted ALD oxide devices, however, the formation of PbI₂ is not observed for more than 24 hours at 100° C. While decomposition of MAPbI₃ into its constituents, methylammonium iodide (MAI) and PbI₂ is well-known at elevated temperature, it is believed that the ALD oxide electron extraction layer may also serve as a barrier not only to the ingress of moisture and/or oxygen, but also impedes the outward diffusion of MAI which might otherwise beneficially equilibrate with the solid perovskite phase.

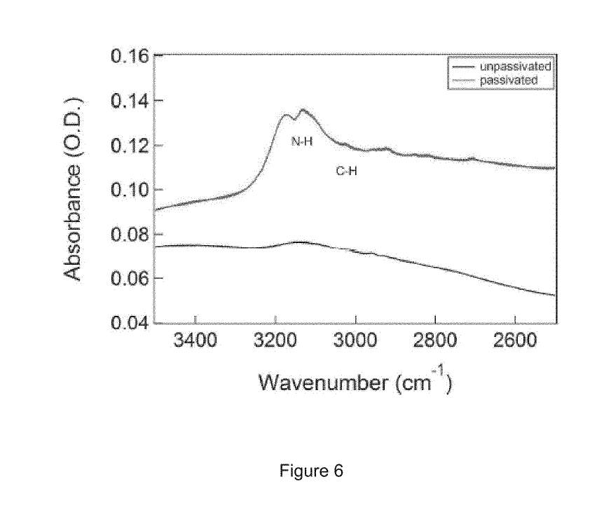

FIG. 6 shows FTIR spectra of unpassivated (glass/perovskite/PCBM) and passivated (glass/perovskite/PCBM/a-TiO₂) samples after thermal cycling at 100° C. in air. Characteristic vibrational modes of methylammonium (CH₃NH₂+) ions disappear in the unpassivated sample (black curve) upon degradation, whereas CH₃NH₂₊ species are preserved in the passivated sample. Measurements were performed with samples prepared on glass without contact electrodes to minimize complexity of FTIR measurements.

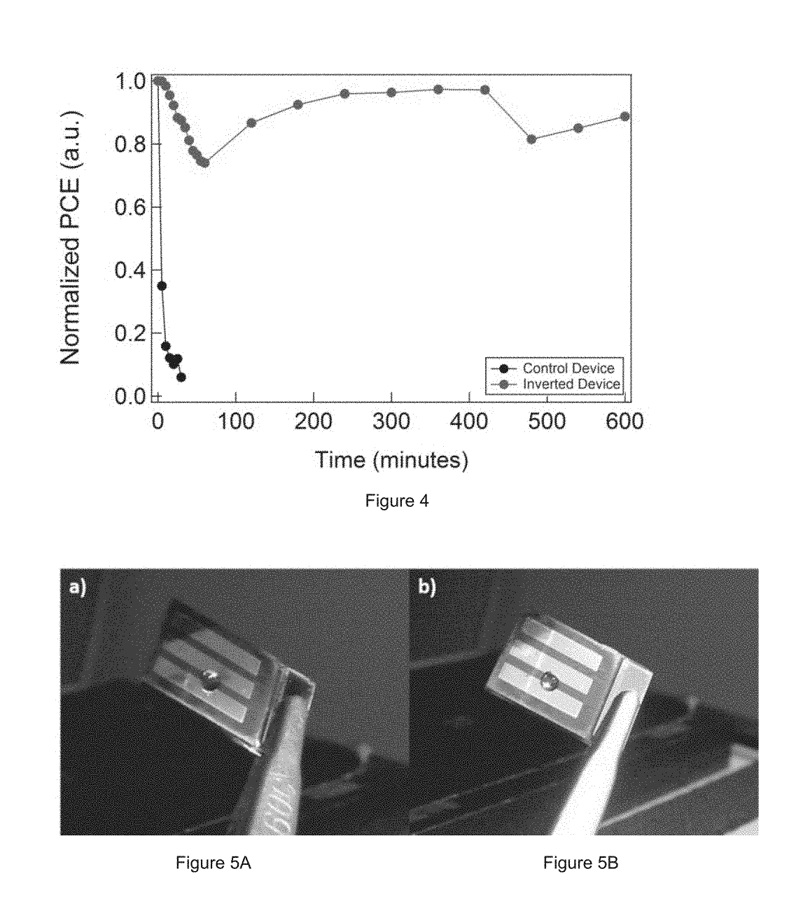

Further, I-V measurements were performed of the devices after thermal cycling at 100° C. (FIG. 4). The efficiency of standard cell exhibits a significant reduction (35% initial efficiency) just after 5 minutes, which is in qualitative agreement with previous reports. The rate of degradation in device performance exceeds that of the structural degradation of the halide perovskite photoabsorber alone observed using XRD, possibly owing to the concurrent degradation of the hygroscopic organic hole extraction material (spiro-OMeTAD) upon thermal cycling. Li doping of spiro-OMeTAD has previously been shown to aggravate moisture penetration in hybrid perovskite devices accelerating performance degradation. The inverted perovskite device, on the other hand, endures thermal soaking at 100° C. in ambient air for more than 10 hours with a stable normalized device efficiency of ˜91% on average throughout the measurement. At 100° C., a continuous decrease in efficiency was observed in the initial 60 minutes with short (5 minute) measurement intervals, which is recovered in the following measurements with longer (1 hour) measurement intervals. It is believed, without limiting the scope described herein, that the slow reduction in photocurrent may arise from the formation of light activated metastable deep level trap states owing to an almost continuous light soaking for the initial 60 minutes. These light activated trap states are known to annihilate if the device is rested in the dark, resulting in a nearly full self-recovery of the device. The recovery of efficiency in the subsequent measurements with long measurement (or light soaking) intervals is also consistent with the dissipation of light activated deep level trap states. Based on the drastic difference in stabilities between conventional and inverted perovskite devices, it is believed that potentially pinhole-free ultrathin a-TiO₂ ALD films not only serve as an efficient moisture/oxygen barrier, but also suppresses egress of MAI upon thermal degradation, ultimately stabilizing halide perovskite photoabsorbers against thermal stress. Moreover, the conformal growth afforded by the ALD layer ensures a complete and continuous coverage of a-TiO₂ over the most complex absorber topologies. This is a clear advantage compared to sputtering which is subject to line-of-sight limitations that may result in pinholes in the presence even the smallest surface contamination/dust.

The inverted ALD oxide perovskite devices were further tested under the extreme conditions of direct liquid water exposure without further encapsulation (FIGS. 5A and 5B). A drop of water was placed that spanned the exposed gold electrode and a-TiO₂ coating (electrode-free area) of an inverted perovskite device prior to I-V measurement and remained on the device for the duration of measurement—dark and illuminated I-V measurements. Strikingly, the inverted devices exhibit stable operation during the entire 3 minute measurement despite the presence of liquid water. Analogous devices were rinsed under running water for 10 seconds without any visual signs of degradation nor subsequent performance loss. To the best of our knowledge this is the first report of a nanoscale integrated barrier (without post-encapsulation or thick polymeric capping electrode) that operates during or after exposure to liquid water.

In one embodiment, the structures exhibit resistance to water and temperature with reasonable unoptimized efficiency (average of 8.8%).

In one embodiment, the minimum thickness of PCBM is ˜100 nm of PCBM to protect perovskites against ALD process. In one embodiment, the upper bound temperature for ALD requires a temperature less than 100° C. to maintain integrity of perovskites.

As used herein, the singular forms “a”, “an” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. An apparatus comprising:
a substrate;
an electrode material disposed on the substrate;
a hole extraction layer disposed between the electrode and a perovskite layer;
a buffer layer deposited on the perovskite layer; and
an overcoat layer deposited on the buffer layer.

2. The apparatus of claim 1, wherein the hole extraction layer comprises NiOₓ, PEDOT:PSS, or CuSCN.

3. The apparatus of claim 3, wherein the hole extraction layer has a thickness of 3 nm to 100 nm.

4. The apparatus of claim 1, wherein the perovskite layer comprises a perovskite having a formula of ABX₃, where A is selected from methylammonium (MA), formamidinium (FA), and Cs, B is selected from Pb, Sn, and Bi, and X is selected from I, Cl, and Br.

5. The apparatus of claim 4, wherein the perovskite layer has a thickness of between 300 nm and 1000 nm.

6. The apparatus of claim 5, wherein the perovskite is FAPbI₃.

7. The apparatus of claim 1, wherein the buffer layer comprises an organic buffer layer comprising a fullerene.

8. The apparatus of claim 7, wherein the buffer layer is [6,6]-phenyl-C₆₁-butyric acid methyl ester.

9. The apparatus of claim 1, wherein the buffer layer comprises inorganic nanoparticles.

10. The apparatus of claim 1, wherein the buffer layer has a thickness of about 5 to 500 nm.

11. The apparatus of claim 1, wherein the overlayer is selected from the group comprising metal oxide, metal nitride, and metal sulfide.

12. The apparatus of claim 11, wherein the overlayer is amorphous.

13. The apparatus of claim 11, wherein the amorphous overlayer has a thickness of less than 10 nm.

14. The apparatus of claim 1, further comprising one or more electrodes disposed on the overlayer.

15. A method comprising:
providing a substrate with a transparent electrode material thereon;
depositing a hole extraction layer on the transparent electrode material;
depositing a perovskite layer on the compact hole extraction layer;
depositing a buffer layer on a perovskite layer; and
depositing, by atomic layer deposition, a metal halide overlayer on the organic buffer layer.

16. The method of claim 15, wherein the deposition by atomic layer deposition comprises a temperature of 50° C. to 200° C., a pressure of 1×10-6 Torr to 800 Torr, and an ALD pulse cycle timing of 0.001 to 10 seconds.

17. The method of claim 15, wherein the hole extraction layer comprises NiOₓ, PEDOT:PSS, or CuSCN and has a thickness of 3 nm to 100 nm.

18. The method of claim 15, wherein the perovskite layer comprises a perovskite having a formula of ABX₃, where A is selected from methylammonium (MA), formamidinium (FA), and Cs, B is selected from Pb, Sn, and Bi, and X is selected from I, Cl, and Br and further wherein the perovskite layer has a thickness of between 300 nm and 1000 nm.

19. The apparatus of claim 1, wherein the buffer layer comprises an organic buffer layer comprising a fullerene and has a thickness of about 5 to 500 nm.

20. The apparatus of claim 1, wherein the overlayer has a thickness of less than 10 nm.
